(19) United States
(12) Patent Application Publication
(10) Pub. No.: US 2024/0292759 A1
(43) Pub. Date: Aug. 29, 2024

(54) MAGNETIC MEMORY ELEMENT AND SEMICONDUCTOR DEVICE

(71) Applicant: SONY SEMICONDUCTOR SOLUTIONS CORPORATION, KANAGAWA (JP)

(72) Inventors: YO SATO, KANAGAWA (JP); EIJI KARIYADA, KANAGAWA (JP); HIRONOBU TANIGAWA, KANAGAWA (JP); HIROKI TANABE, KANAGAWA (JP); HIROYUKI UCHIDA, KANAGAWA (JP); MASAKI ENDO, KANAGAWA (JP); YUITO KAGEYAMA, KANAGAWA (JP)

(21) Appl. No.: 18/573,674

(22) PCT Filed: Mar. 2, 2022
(86) PCT No.: PCT/JP22/08789

§ 371 Date: Dec. 22, 2023

(30) Foreign Application Priority Data
Jul. 1, 2021 (JP) 2021-110141

(51) Int. Cl. H10N 50/80; H10B 61/00; H10N 50/10; H10N 50/85

(52) U.S. Cl. CPC H10N 50/80; H10B 61/00; H10N 50/10; H10N 50/85

(57) ABSTRACT

A magnetic memory element (10) includes a reference layer (11) of which a magnetization direction is fixed, a tunnel barrier layer (12) provided on the reference layer (11), a magnetic storage layer (13) that is provided on the tunnel barrier layer (12) and of which a magnetization direction is changeable, a high Hk application layer (14) that is provided on the magnetic storage layer (13) and improves magnetic anisotropy of the magnetic storage layer (13), and a Cap layer (15) provided on the high Hk application layer (14), and a material of the high Hk application layer (14) is different from a material of the Cap layer (15), and the material of the high Hk application layer (14) is a high melting point metal.

### FIELD

The present disclosure relates to a magnetic memory element and a semiconductor device.

### BACKGROUND

For example, Patent Literature 1 discloses a magnetic memory element that includes a storage layer and a cap layer provided on the storage layer.

### CITATION LIST

### Patent Literature

Patent Literature 1: JP 2020-35976 A

### SUMMARY

### Technical Problem

For example, in a case where a magnetic memory element is provided on a semiconductor substrate, a coercive force of the magnetic memory element is lowered due to a thermal load during a semiconductor process. It is required to have an appropriate coercive force even after the coercive force is lowered by the thermal load.

One aspect of the present disclosure provides a magnetic memory element and a semiconductor device capable of having an appropriate coercive force after a coercive force is lowered by a thermal load.

### Solution to Problem

A magnetic memory element according to one aspect of the present disclosure includes: a reference layer of which a magnetization direction is fixed; a tunnel barrier layer provided on the reference layer; a magnetic storage layer configured to be provided on the tunnel barrier layer and of which a magnetization direction is changeable; a high Hk application layer configured to be provided on the magnetic storage layer and improve magnetic anisotropy of the magnetic storage layer; and a Cap layer provided on the high Hk application layer, wherein a material of the high Hk application layer is different from a material of the Cap layer, and the material of the high Hk application layer is a high melting point metal.

A semiconductor device according to one aspect of the present disclosure includes a plurality of magnetic memory elements arranged on a semiconductor substrate, wherein the magnetic memory element includes a reference layer of which a magnetization direction is fixed, a tunnel barrier layer provided on the reference layer, a magnetic storage layer that is provided on the tunnel barrier layer and of which a magnetization direction is changeable, a high Hk application layer that is provided on the magnetic storage layer and improves magnetic anisotropy of the magnetic storage layer, and a Cap layer provided on the high Hk application layer, and a material of the high Hk application layer is different from a material of the Cap layer, and the material of the high Hk application layer is a high melting point metal.

### BRIEF DESCRIPTION OF DRAWINGS

FIG. 1 is a diagram illustrating an example of a schematic configuration of a memory element according to an embodiment.

FIG. 2 is a diagram illustrating an example of a coercive force obtained by a high Hk application layer.

FIG. 3 is a diagram illustrating an example of another shape of the high Hk application layer.

FIG. 4 is a diagram illustrating an example of a schematic configuration of a semiconductor device according to the embodiment.

### DESCRIPTION OF EMBODIMENTS

Hereinafter, an embodiment of the present disclosure will be described in detail with reference to the drawings. Note that, in each embodiment below, redundant description is omitted by denoting the same element with the same reference numeral. Note that a size of each element illustrated in the drawings is not necessarily accurate.

The present disclosure will be described according to the following order of items.
1. Embodiment
1.1 Magnetic Memory Element
1.2 Semiconductor Device
2. Example of Applications
3. Example of Effects

### 1. Embodiment

### 1.1 Magnetic Memory Element

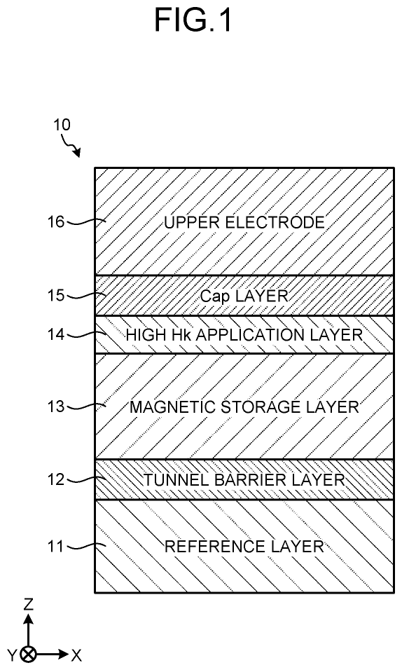

FIG. 1 is a diagram illustrating an example of a schematic configuration of a magnetic memory element according to an embodiment. The magnetic memory element is a magnetic tunnel junction (MTJ) element using tunneling magnetoresistance effects (TMR) and has a laminated structure. In FIG. 1, an XYZ coordinate system is illustrated. A Z-axis direction corresponds to a laminating direction (vertical direction). An X-axis direction and a Y-axis direction correspond to a layer extending direction (plane direction).

A magnetic memory element 10 includes a reference layer 11, a tunnel barrier layer 12, a magnetic storage layer 13, a high Hk application layer 14, a Cap layer 15, and an upper electrode 16. In the example illustrated in FIG. 1, the reference layer 11, the tunnel barrier layer 12, the magnetic storage layer 13, the high Hk application layer 14, the Cap layer 15, and the upper electrode 16 are laminated in this order toward the Z-axis positive direction.

A magnetization direction (direction of magnetic moment) of the reference layer 11 is fixed, and the reference layer 11 gives a magnetization direction to be a reference. The reference layer 11 includes a ferromagnetic substance so as to have a high coercive force. Examples of a material of the reference layer 11 are Fe, Co, Ni, Mn, or the like, and more specifically, CoFeB, FeNiB, FeCoC, CoFe, CoPt, FePt, CoMnSi, MnAl, or the like. Furthermore, a configuration in which these materials are laminated and a laminated ferry configuration in which these materials are coupled magnetically antiparallel via Ru and Ir may be used. An example of a thickness (layer thickness) of the reference layer 11 is about one nm to about 30 nm. The reference layer 11 is also referred to as a reference layer, a fixed layer, or the like.

The magnetization direction may be a magnetization direction in the Z-axis direction. By using a material having perpendicular magnetic anisotropy, it is possible to reduce power, increase a capacity, or the like of the magnetic memory element 10 than those in a case where a material having in-plane magnetic anisotropy is used.

The tunnel barrier layer 12 is provided on the reference layer 11. “Provided on the layer” basically indicates a state where layers have contact with each other (for example, surface contact) in the Z-axis direction. However, the layers may be separated from each other (for example, another element may be interposed therebetween) as long as the function of each layer is not impaired. The tunnel barrier layer 12 couples the reference layer 11 and the magnetic storage layer 13 by a tunnel effect. The tunnel barrier layer 12 includes a non-magnetic body. Examples of a material of the tunnel barrier layer 12 are MgO, Al₂O₃, AlN, SiO₂, Bi₂O₃, MgF₂, CaF, SrTiO₂, AlLaO₃, AlNO, or the like. In the embodiment, the material of the tunnel barrier layer 12 may include MgO. A magnetoresistance change ratio (MR ratio) can be higher than that in a case where another material is used. An example of a layer thickness of the tunnel barrier layer 12 is about 0.3 nm to about five nm.

The magnetic storage layer 13 is provided on the tunnel barrier layer 12. The magnetic storage layer 13 includes a ferromagnetic substance. Similarly to the reference layer 11, examples of a material of the magnetic storage layer 13 are Fe, Co, Ni, Mn, or the like, and more specifically, CoFeB, FeNiB, FeCoC, CoFe, CoPt, FePt, CoMnSi, MnAl, or the like. An example of a layer thickness of the magnetic storage layer 13 is about one nm to about 10 nm. Unlike the reference layer 11, the magnetic storage layer 13 is a layer of which the magnetization direction can be changed (inverted). For example, to invert a magnetic moment, for example, spin torque magnetic reversal is used. By inverting the magnetic moment of the magnetic storage layer 13, binary information of one or zero can be written.

The high Hk application layer 14 is provided on the magnetic storage layer 13. The high Hk application layer 14 will be described layer.

The Cap layer 15 is provided on the high Hk application layer 14. The Cap layer 15 covers (cap) layers positioned below (Z-axis negative direction side) the Cap layer 15, that is, the high Hk application layer 14, the magnetic storage layer 13, the tunnel barrier layer 12, and the reference layer 11. The Cap layer 15 has an effect of promoting crystallization of the magnetic storage layer 13, together with the tunnel barrier layer 12. An example of a material of the Cap layer 15 is a nonmagnetic oxide. An example of the nonmagnetic oxide is a rare earth oxide such as MgO, Gd, Tb, Dy, or Sc. An example of a film thickness of the Cap layer 15 is about 0.5 nm to about 10 nm. The upper electrode 16 is provided on the Cap layer 15. The upper electrode 16 provides electrical connection with outside of the magnetic memory element 10. The upper electrode 16 functions as a wiring line or functions as a hard mask. Examples of a material of the upper electrode are metal materials such as Ru, Mo, Ta, TaN, TiN, or CoFeB.

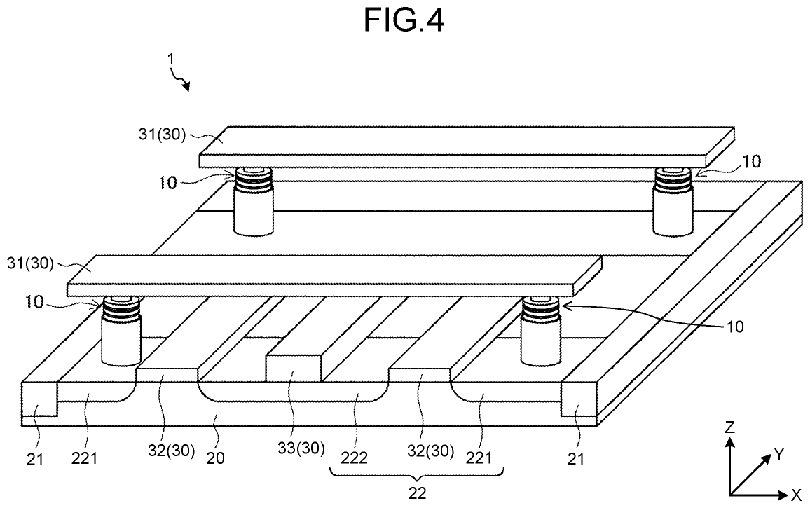

Note that, although not illustrated, the magnetic memory element 10 may include an underlayer or a lower electrode under (Z-axis negative direction side) the reference layer 11. For example, the underlayer is provided between the reference layer 11 and a substrate (for example, semiconductor substrate 20 in FIG. 4 to be described layer) and improves crystal orientation control of the reference layer 11 and an adherence strength with respect to the substrate. A material of the underlayer may be a material having crystal orientation that substantially matches the reference layer 11. The lower electrode is provided below the underlayer, and sandwiches the Cap layer 15, the high Hk application layer 14, the magnetic storage layer 13, the tunnel barrier layer 12, the reference layer 11, and the underlayer, in the Z-axis direction, together with the upper electrode 16 and provides electrical connection with the outside of the magnetic memory element 10.

In the present embodiment, the high Hk application layer 14 is provided between the magnetic storage layer 13 and the Cap layer 15. The high Hk application layer 14 improves a coercive force of the magnetic memory element 10. Hereinafter, the coercive force of the magnetic memory element 10 is referred to as a coercive force Hc. An example of a unit of the coercive force Hc is oersted (Oe). The coercive force Hc is proportional to magnetic anisotropy of the magnetic storage layer 13. The magnetic anisotropy is referred to as magnetic anisotropy Hk. The high Hk application layer 14 improves the coercive force Hc of the magnetic memory element 10, by providing the high magnetic anisotropy Hk to the magnetic memory element 10.

The high Hk application layer 14 does not prevent bcc (001) crystallization of the magnetic storage layer 13 at the time of heat treatment in a manufacturing process or the like and suppresses material diffusion from the Cap layer 15. An example of the high Hk application layer 14 is a high melting point metal. An example of a melting point of a high melting point metal material is equal to or higher than 2000° C. The high melting point material may be a material having a bcc crystal or an amorphous structure. Examples of the high melting point metal material are W, Mo, Ta, or the like. An alloy containing Co, Fe, B (boron), or the like in these materials may be the high Hk application layer 14. An example of such an alloy is CoFeMo or the like. An example of an upper limit value of a layer thickness of the high Hk application layer 14 is 1.0 nm. The high Hk application layer 14 has a film thickness equal to or less than 1.0 nm so that an effect of not preventing crystallization from the Cap layer 15 is easily obtained. An example of a lower limit value of the layer thickness of the high Hk application layer 14 is 0.2 nm or the like. The high Hk application layer 14 has the layer thickness equal to or more than 0.2 nm so that an effect of suppressing material diffusion from the Cap layer 15 and the upper electrode 16 is easily obtained.

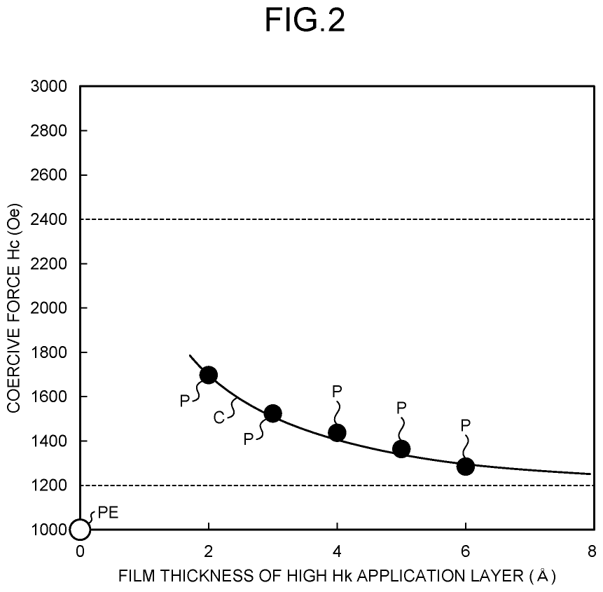

FIG. 2 is a diagram illustrating an example of a coercive force obtained by the high Hk application layer. The horizontal axis of the graph indicates the film thickness (A) of the high Hk application layer 14, and the vertical axis indicates the coercive force Hc (Oe) of the magnetic memory element 10. The coercive force Hc indicated in the graph is a coercive force Hc after the coercive force is lowered by a thermal load. In this example, the thermal load is heating at 400 degrees for three hours. The material of the tunnel barrier layer 12 is MgO. The material of the magnetic storage layer 13 is CoFeB. The material of the high Hk application layer 14 is Mo. The material of the Cap layer 15 is MgO.

A plot P indicates a measured value of the coercive force Hc of the magnetic memory element 10, and a graph line C passes through these plots P. A plot PE indicates a measured value of a coercive force Hc of a magnetic memory element according to a comparative example in which the layer thickness of the high Hk application layer 14 is zero, that is, the high Hk application layer 14 is not included. A lower limit value 1200 Oe and an upper limit value 2400 Oe of a range of the practical coercive force Hc are indicated by broken lines.

In a case where the high Hk application layer 14 is not included, as indicated by the plot PE, the coercive force Hc after the coercive force is lowered by the thermal load is only about 1000 Oe, which is out of a practical range. It is not possible to obtain a sufficient coercive force Hc to store magnetization information.

In a case where the high Hk application layer 14 is included, as indicated by the plot P and the graph line C, the coercive force Hc after the coercive force is lowered by the thermal load is positioned within the practical range. As the thickness of the high Hk application layer 14 decreases, the coercive force Hc increases. Although not illustrated, if the thickness becomes too small, the coercive force Hc decreases and approaches a value indicated by the plot PE. By adjusting the layer thickness of the high Hk application layer 14, the coercive force Hc equal to or more than 1200 Oe is obtained, and in addition, there is a possibility that the coercive force Hc equal to or more than 1800 Oe is obtained, for example. Although not illustrated, in a case where the high Hk application layer 14 is included, a larger TMR than that in a case where the high Hk application layer 14 is not included is obtained.

As described above, by including the high Hk application layer 14, the magnetic memory element 10 can have an appropriate coercive force Hc, for example, a coercive force Hc within a range of 1200 Oe to 2400 Oe even after the coercive force is lowered by the thermal load. An appropriate TMR can be also obtained. Both good coercivity (thermal stability) and the TMR can be achieved.

As an application example, the magnetic memory element 10 having the coercive force Hc of 1200 Oe can be used as a static random access memory (SRAM) replacement type magnetoresistive random access memory (MRAM) having high-speed writing characteristics. The magnetic memory element 10 having the coercive force Hc larger than 1800 Oe can be used as a non-volatile memory that can be magnetized for 10 or more years.

Note that, not providing the high Hk application layer 14 in order to realize a structure that endures the thermal load, it is conceivable to further suppress thermal diffusion by increasing the layer thickness of the Cap layer 15. However, if the layer thickness of the Cap layer 15 becomes too large, the TMR is lowered due to parasitic resistance. It is often difficult to design the layer thickness of the Cap layer 15 that achieves both of the large magnetic anisotropy and the high TMR. Such a problem is solved by providing the high Hk application layer 14 separately from the Cap layer 15.

Information is written in the magnetic memory element 10, for example, by the spin torque magnetic reversal as described above. By making a current flow between the electrodes (between upper electrode 16 and lower electrode not illustrated), the magnetization direction of the magnetic storage layer 13 is inverted, and information according to the magnetization direction is written (stored) in the magnetic storage layer 13.

Information is read from the magnetic memory element 10 using the TMR effect. That is, in the magnetic memory element 10, a magnitude of an electrical resistance between the electrodes changes according to a relationship between the magnetization direction of the reference layer 11 and the magnetization direction of the magnetic storage layer 13 (for example, parallel or antiparallel). By detecting the electrical resistance by detecting the current, the magnetization direction of the magnetic storage layer 13, that is, the information written (stored) in the magnetic storage layer 13 is read. Note that a current at the time of reading is much smaller than a current at the time of writing and does not affect the magnetization direction of the magnetic storage layer 13. Therefore, it is possible to read information in a non-destructive manner.

A method of manufacturing the magnetic memory element 10 will be described. For example, the manufacturing method includes a process of preparing a semiconductor substrate such as a silicon substrate (not illustrated), a process of laminating a plurality of layers included in the magnetic memory element 10 on the prepared semiconductor substrate so as to obtain a laminated structure, or the like. In the lamination process, the underlayer, the lower electrode, the reference layer 11, the tunnel barrier layer 12, the magnetic storage layer 13, the high Hk application layer 14, the Cap layer 15, and the upper electrode 16 described above are laminated in this order, for example, through film formation or the like. The manufacturing method may include a process of heating the laminated structure. Heating may be performed after the lamination process is completed or may be performed during the lamination process, for example, each time after film formation of each layer. The heating process may be a heating process during the semiconductor process and is a process for applying a thermal load of 400 degrees for three hours to the laminated structure as described above, for example. As described above, an appropriate coercive force Hc can be obtained even after such a thermal load is applied.

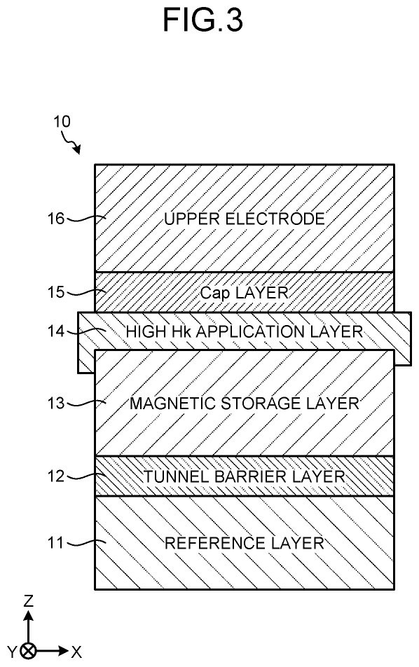

Note that, in the manufacturing process, edge portions of some layers may extend to a position of another layer. This will be described with reference to FIG. 3.

FIG. 3 is a diagram illustrating an example of a schematic configuration of the magnetic memory element. In this example, an edge portion of the high Hk application layer 14 extends to the position of the magnetic storage layer 13 positioned below the high Hk application layer 14. The edge portion may enter the magnetic storage layer 13. Even with the high Hk application layer 14 having such a shape, naturally, it is possible to improve the coercive force Hc of the magnetic memory element 10, as described above. The layer thickness of the high Hk application layer 14 in this case may be a thickness of a portion excluding the edge portion.

### 1.2 Semiconductor Device

FIG. 4 is a diagram illustrating an example of a schematic configuration of a semiconductor device according to the embodiment. An exemplified semiconductor device 1 is a magnetic memory (magnetic storage device). The semiconductor device 1 includes the magnetic memory element 10, a semiconductor substrate 20, and wiring 30. The semiconductor substrate 20 is, for example, a semiconductor substrate such as a silicon substrate. As the wiring 30, a bit line 31, a word line 32, and a sense line 33 are exemplified. The bit line 31 and the word line 32 are two types of address lines crossing each other. In this example, the bit line 31 extends in the X-axis direction, and the word line 32 extends in the Y-axis direction. The sense line 33 extends in a direction same as the word line 32 in this example.

The magnetic memory element 10 includes a plurality of magnetic memory elements 10 arranged on the semiconductor substrate 20 (Z-axis positive direction side in this example). Each magnetic memory element 10 is arranged near an intersection between the bit line 31 and the word line 32 (for example, in an array). One terminal of the magnetic memory element 10 is electrically connected to the bit line 31. For example, the upper electrode 16 of the magnetic memory element 10 described above is electrically connected to the bit line 31. Another terminal of the magnetic memory element 10 is electrically connected to a selection transistor 22 to be described later. For example, the lower electrode of the magnetic memory element 10 described above is electrically connected to the selection transistor 22.

The semiconductor substrate 20 includes an element isolation region 21 and the selection transistor 22. The element isolation region 21 provides an electrically isolated region. The selection transistor 22 is formed in the region isolated by the element isolation region 21. The selection transistor 22 is provided so as to select the magnetic memory element 10.

The single magnetic memory element 10 and the single selection transistor 22 used to select the magnetic memory element 10 form a single memory cell. The plurality of memory cells is arranged on the semiconductor substrate 20. In FIG. 4, a portion corresponding to four memory cells is schematically illustrated.

The exemplified selection transistor 22 is an FET and includes a source region 221, a drain region 222, and a gate region. The source region 221 and the drain region 222 are formed on the semiconductor substrate 20. A gate electrode provided for the gate region is included in the word line 32.

The source region 221 is electrically connected to another terminal of the magnetic memory element 10. The drain region 222 is electrically connected to the sense line 33. Note that, in this example, the drain region 222 is formed in common with the drain region 222 of the adjacent selection transistor 22.

The magnetic memory element 10 is electrically connected between the source region 221 of the selection transistor 22 and the bit line 31, in the Z-axis direction. The electrical connection is established, for example, via a contact layer or the like.

The bit line 31, the word line 32, and the sense line 33 are connected to a power supply circuit or the like (not illustrated) so as to flow a desired current into the magnetic memory element 10 (between upper and lower electrodes). At the time of writing information, a voltage to flow the current to the magnetic memory element 10 is applied via the bit line 31 and the sense line 33 corresponding to a desired memory cell. A voltage is applied to the word line 32 corresponding to the desired memory cell, that is, the gate electrode of the selection transistor 22, and the selection transistor 22 is turned on (conductive state), so that the current flows in the magnetic memory element 10. The current flows in the magnetic memory element 10, and the information is written (stored) by the spin torque magnetic reversal as described above. At the time of reading information, a voltage is applied to the word line 32 corresponding to the desired memory cell, that is, the gate electrode of the selection transistor 22, and a current flowing between the bit line 31 and the sense line 33, that is, a current flowing through the magnetic memory element 10 is detected. The detection of the current means detection of a magnitude of the electrical resistance, and information is read through this detection.

By including the magnetic memory element 10, the semiconductor device 1 can have the appropriate coercive force Hc even after the coercive force is lowered by the thermal load, similarly to the magnetic memory element 10. In the method of manufacturing the semiconductor device 1, the semiconductor substrate 20 serves as the semiconductor substrate in the method of manufacturing the magnetic memory element 10 described above. The method of manufacturing the semiconductor device 1 further includes a process of forming the element isolation region 21 and the selection transistor 22 on the semiconductor substrate 20, a process of forming the wiring 30, or the like.

### 2. Example of Applications

The semiconductor device 1 including the magnetic memory element 10 described above can be used for various applications. For example, the semiconductor device 1 is mounted on an electronic device to be used. Examples of the electronic device are a game machine, a mobile device such as a smartphone or a tablet terminal, a notebook PC, a wearable device, a music device, a video device, a digital camera, or the like. The semiconductor device 1 is used as a storage, a temporary storage memory, or the like. The magnetic memory element 10 may be an MTJ element used for a magnetic head. The magnetic memory element 10 can be applied to a hard disk drive on which the magnetic head is mounted, a magnetic sensor device, or the like.

### 3. Example of Effects

The technology described above is specified as follows, for example. One of the disclosed technology is the magnetic memory element 10. As described with reference to FIGS. 1 to 3, the magnetic memory element 10 includes the reference layer 11 of which the magnetization direction is fixed, the tunnel barrier layer 12 provided on the reference layer 11, the magnetic storage layer 13 that is provided on the tunnel barrier layer 12 and of which the magnetization direction can be changed, the high Hk application layer 14 that is provided on the magnetic storage layer 13 and improves the magnetic anisotropy of the magnetic storage layer 13, and the Cap layer 15 provided on the high Hk application layer 14. The material of the high Hk application layer 14 is different from the material of the Cap layer 15. The material of the high Hk application layer 14 is a high melting point metal.

According to the magnetic memory element 10 described above, by including the high Hk application layer 14 separately from the Cap layer 15, it is possible to have an appropriate coercive force Hc (for example, equal to or more than 1200 Oe) even after the coercive force is lowered by the thermal load (for example, thermal load during semiconductor process).

The material of the high Hk application layer 14 may include at least one of W, Mo, and Ta. In that case, the material of the high Hk application layer may further include at least one of Co, Fe, and B (that is, may be such alloy). Furthermore, the layer thickness of the high Hk application layer 14 may be equal to or more than 0.2 nm and equal to or less than 1.0 nm. For example, by including the high Hk application layer 14 with such a material and a layer thickness, it is possible to obtain an appropriate coercive force Hc even after the coercive force is lowered by the thermal load.

The material of the Cap layer 15 may include a nonmagnetic oxide. In that case, the material of the Cap layer 15 may include at least one of MgO, Gd, Tb, Dy, and Sc. For example, by including the high Hk application layer 14 separately from such a Cap layer 15, it is possible to obtain an appropriate coercive force Hc even after the coercive force is lowered by the thermal load.

The material of the high Hk application layer 14 may include Mo, and the material of the Cap layer 15 may include MgO. In that case, the material of the tunnel barrier layer 12 may include MgO, and the material of the magnetic storage layer 13 may include CoFeB. For example, by including these layers, it is possible to obtain an appropriate coercive force Hc even after the coercive force is lowered by the thermal load.

The semiconductor device 1 described with reference to FIG. 4 or the like is one of the disclosed technologies. The semiconductor device 1 includes the plurality of magnetic memory elements 10 arranged on the semiconductor substrate 20. According to such a semiconductor device 1, it is possible to obtain an appropriate coercive force Hc even after the coercive force is lowered by the thermal load, as described above.

Note that the effects described in the present disclosure are merely examples and are not limited to the disclosed content. The other effects may be achieved.

Although the embodiment of the present disclosure has been described above, the technical scope of the present disclosure is not limited to the embodiment described above, and various modifications can be made without departing from the gist of the present disclosure.

Note that the present technology can have the following configurations.
(1) A magnetic memory element comprising:
   a reference layer of which a magnetization direction is fixed;
   a tunnel barrier layer provided on the reference layer;
   a magnetic storage layer configured to be provided on the tunnel barrier layer and of which a magnetization direction is changeable;
   a high Hk application layer configured to be provided on the magnetic storage layer and improve magnetic anisotropy of the magnetic storage layer; and
   a Cap layer provided on the high Hk application layer, wherein
   a material of the high Hk application layer is different from a material of the Cap layer, and
   the material of the high Hk application layer is a high melting point metal.
(2) The magnetic memory element according to (1), wherein
   the material of the high Hk application layer includes at least one of W, Mo, and Ta.
(3) The magnetic memory element according to (2), wherein
   the material of the high Hk application layer further includes at least one of Co, Fe, and B.
(4) The magnetic memory element according to any one of (1) to (3), wherein
   a layer thickness of the high Hk application layer is equal to or more than 0.2 nm and equal to or less than 1.0 nm.
(5) The magnetic memory element according to any one of (1) to (4), wherein
   the material of the Cap layer is a nonmagnetic oxide.
(6) The magnetic memory element according to any one of (1) to (5), wherein
   the material of the Cap layer includes at least one of MgO, Gd, Tb, Dy, and Sc.
(7) The magnetic memory element according to any one of (1) to (6), wherein
   the material of the high Hk application layer includes Mo, and
   the material of the Cap layer includes MgO.
(8) The magnetic memory element according to any one of (1) to (7), wherein
   a material of the tunnel barrier layer includes MgO,
   a material of the magnetic storage layer includes CoFeB,
   the material of the high Hk application layer includes Mo, and
   the material of the Cap layer includes MgO.
(9) The magnetic memory element according to any one of (1) to (8), wherein
   a coercive force after being lowered by a thermal load during a semiconductor process is equal to or more than 1200 Oe.
(10) A semiconductor device comprising
   a plurality of magnetic memory elements arranged on a semiconductor substrate, wherein
   the magnetic memory element includes
   a reference layer of which a magnetization direction is fixed,
   a tunnel barrier layer provided on the reference layer,
   a magnetic storage layer that is provided on the tunnel barrier layer and of which a magnetization direction is changeable,
   a high Hk application layer that is provided on the magnetic storage layer and improves magnetic anisotropy of the magnetic storage layer, and
   a Cap layer provided on the high Hk application layer, and
   a material of the high Hk application layer is different from a material of the Cap layer, and
   the material of the high Hk application layer is a high melting point metal.

### REFERENCE SIGNS LIST

1 SEMICONDUCTOR DEVICE
10 MAGNETIC MEMORY ELEMENT
11 REFERENCE LAYER
12 TUNNEL BARRIER LAYER
13 MAGNETIC STORAGE LAYER
14 HIGH HK APPLICATION LAYER
15 CAP LAYER
16 UPPER ELECTRODE
20 SEMICONDUCTOR SUBSTRATE
21 ELEMENT ISOLATION REGION
22 SELECTION TRANSISTOR
221 SOURCE REGION
222 DRAIN REGION
30 WIRING
31 BIT LINE
32 WORD LINE
33 SENSE LINE

1. A magnetic memory element comprising:
a reference layer of which a magnetization direction is fixed;
a tunnel barrier layer provided on the reference layer;
a magnetic storage layer configured to be provided on the tunnel barrier layer and of which a magnetization direction is changeable;
a high Hk application layer configured to be provided on the magnetic storage layer and improve magnetic anisotropy of the magnetic storage layer; and
a Cap layer provided on the high Hk application layer, wherein
a material of the high Hk application layer is different from a material of the Cap layer, and
the material of the high Hk application layer is a high melting point metal.

2. The magnetic memory element according to claim 1, wherein
the material of the high Hk application layer includes at least one of W, Mo, and Ta.

3. The magnetic memory element according to claim 2, wherein
the material of the high Hk application layer further includes at least one of Co, Fe, and B.

4. The magnetic memory element according to claim 1, wherein
a layer thickness of the high Hk application layer is equal to or more than 0.2 nm and equal to or less than 1.0 nm.

5. The magnetic memory element according to claim 1, wherein
the material of the Cap layer is a nonmagnetic oxide.

6. The magnetic memory element according to claim 1, wherein
the material of the Cap layer includes at least one of MgO, Gd, Tb, Dy, and Sc.

7. The magnetic memory element according to claim 1, wherein
the material of the high Hk application layer includes Mo, and
the material of the Cap layer includes MgO.

8. The magnetic memory element according to claim 1, wherein
a material of the tunnel barrier layer includes MgO,
a material of the magnetic storage layer includes CoFeB,
the material of the high Hk application layer includes Mo, and
the material of the Cap layer includes MgO.

9. The magnetic memory element according to claim 1, wherein
a coercive force after being lowered by a thermal load during a semiconductor process is equal to or more than 1200 Oe.

10. A semiconductor device comprising
a plurality of magnetic memory elements arranged on a semiconductor substrate, wherein
the magnetic memory element includes
a reference layer of which a magnetization direction is fixed,
a tunnel barrier layer provided on the reference layer,
a magnetic storage layer that is provided on the tunnel barrier layer and of which a magnetization direction is changeable,
a high Hk application layer that is provided on the magnetic storage layer and improves magnetic anisotropy of the magnetic storage layer, and
a Cap layer provided on the high Hk application layer, and
a material of the high Hk application layer is different from a material of the Cap layer, and
the material of the high Hk application layer is a high melting point metal.
